(19) United States
(12) Patent Application Publication
(10) Pub. No.: US 2007/0107771 A1
(43) Pub. Date: May 17, 2007

(54) Apparatus and means of production of transparent nano-wire containing batteries, lights, CPUs, solar collectors, and other components

(76) Inventor: Daryl Lee Tempesta, Scotts Valley, CA (US)

Correspondence Address: STEVEN A. NIELSEN;ALLMAN & NIELSEN, P.C, 100 Larkspur Landing Circle, Suite 212, LARKSPUR, CA, 94939, US

(21) Appl. No.: 11/465,764

(22) Filed: Aug. 18, 2006

Related U.S. Application Data
(60) Provisional application No. 60/595,977, filed on Aug. 22, 2005.

(51) Int. Cl. G06F 13/00; H01L 31/00; H01M 2/10

(52) U.S. Cl. 136/252; 429/96; 710/100

(57) ABSTRACT

Means and methods of producing flexible transparent nano-wire containing batteries, solar cells, lights, and CPUs are disclosed. The disclosed invention provides new means for solar energy collection, power storage, light generation, and portable computing in the form of nano-sized wire or tubes. The disclosed nanotubes and larger sizes of tubes may be combined to create components capable of being handled by human hands or traditional construction methods. The disclosed tubes may have a diameter larger than nano size and otherwise be scaled as needed.

### CROSS-REFERENCE TO RELATED APPLICATIONS

This application claims the benefit and priority date of U.S. provisional application No. 60/595,977, filed on Aug. 22, 2005, entitled “Apparatus and means of production of transparent nano-wire containing batteries, lights, CPUs, solar collectors, and other components” and is herein incorporated by reference.

### STATEMENT REGARDING FEDERALLY SPONSORED RESEARCH OR DEVELOPMENT

Not Applicable.

### REFERENCE TO A SEQUENCE LISTING

Not Applicable.

### BACKGROUND OF THE INVENTION

(1) Field of the Invention

This invention relates to the production and use of nano diameter sized wire with means and methods for power storage, light generation, mobile computing, and solar collection for electricity generation. The disclosed wire or tube may be round to capture energy at 360 degrees and may be used in aggregate to form larger structures suitable for normal handling in traditional construction environments.

(2) Description of the Related Art

The related art fails to provide nano-wire with the capabilities of the present invention. The related art fails to provide means of production or assembly as disclosed in the present invention.

For example, U.S. Pat. No. 7,083,104 by Empedocles, et al discloses means to construct radio frequency identification (RFID) tags with transistors formed by a thin film of nanowires, but fails to provide means to use nanowires or nanotubes to capture solar energy as disclosed in the present invention.

U.S. Pat. No. 7,019,391 by Tran discloses the use of nano ceramic material to remove heat from a nano integrated circuit. The present invention overcomes shortfalls in Tran by disclosing the use of flexible nanotubes containing liquid to remove heat. The nano ceramic material disclosed in Tran is not suitable for cooling or heating the long and flexible nanotubes disclosed in the present invention.

### BRIEF SUMMARY OF THE INVENTION

Means and methods of creating flexible, transparent and nontransparent nano-wire are disclosed. The wire or tubing has means of containing or connecting to solar cells, batteries, lights, computer components, and other components of both nano and non nano scale. The wire or tubing maybe of nano proportions or may be constructed in a larger format.

The disclosed wire may be used as separate computers or several lengths of wire may be used as computing devices in a networked or distributed computing environment.

The disclosed tubing may be used as means to collect solar energy in environments traditionally not amenable to solar collection. The tube may be round or rounded in shape and transparent to allow for solar collection at 360 degrees around the tube. The tube may be wrapped around objects and may be aggregated to form larger components, suitable for handling by human hands and traditional construction practices.

The disclosed wire may be used to provide lighting, used as a sensor array, used as solar paint, used as logic gates, or used in decorative, architectural, or material fill.

These and other aspects and uses of the present invention will become readily apparent upon further review of the following specification and drawings.

### BRIEF DESCRIPTION OF THE DRAWINGS

FIG. 1 is an isometric view of the disclosed wire material or wire conduit enclosed in transparent material.

FIG. 2 is a sectional view of the disclosed wire in continuous, component and segmented form.

FIG. 3 is a sectional view of a plurality of components contained within and/or on the disclosed wire.

FIG. 4 is a sectional view showing methods and means of egress and ingress through the disclosed wire.

FIG. 5 is a sectional view showing means and method of securing the disclosed wire and tapping into the disclosed wire.

FIG. 6 is an elevation view of means and methods of adding and securing connections to the disclosed wire.

FIG. 7 is an elevation view of means and methods of connecting internal and external components to the disclosed wire.

FIG. 8 contains several sectional views of various configurations of the disclosed wire.

FIG. 9 contains several sectional views of the disclosed invention used in several manners, such as a logic gate, solar light switch, emitting device, and feed back or looping system.

FIG. 10 is a sectional view showing means and methods of securing connections, nubs, and handles to the disclosed wire.

FIG. 11 is a sectional view of configurations of the disclosed wire allowing means and methods of recapturing light and electricity.

FIG. 12 is an elevation view of the disclosed wire used as individual computing units and as a network of computing units.

FIG. 13 is a plan view and an exploded view of the disclosed wire used as a display by means of weave and/or pattern placement.

FIG. 14 is a sectional view of means and methods of solar/pigment display in a sphere format.

FIG. 15 is a sectional view showing means and methods of embedding optional components, installing an optional channel for liquids, and transferring data and electricity in and out of the disclosed wire.

FIG. 16 is a sectional view showing means and methods of embedding optional heat sink components and optional tubes for liquid heating o liquid cooling.

### DETAILED DESCRIPTION OF THE INVENTION

Although the following detailed description contains many specific details for the purposes of illustration, anyone of ordinary skill in the art will appreciate that many variations and alterations to the following details are within the scope of the invention. Accordingly, the exemplary embodiments of the invention described below are set forth without any loss of generality to, and without imposing limitations upon, the claimed invention.

Definition List 1

| Term | Definition |
|---|---|
| Nanostructure | Having size of 1 to 10,000 nm |

By way of example, and without limitation, the nanostructures disclosed herein may include flexible or rigid wire or hollow transparent tubing having means to contain solar collectors, batteries, lights, gyroscopes, GPS receivers, and computing components, and/or separate conduit for wire or liquid, Said nanostructures are sometimes collectively referred to herein as “the disclosed wire” or “wire”. The hollow tubing may be transparent, opaque, porous, and/or light permeable.

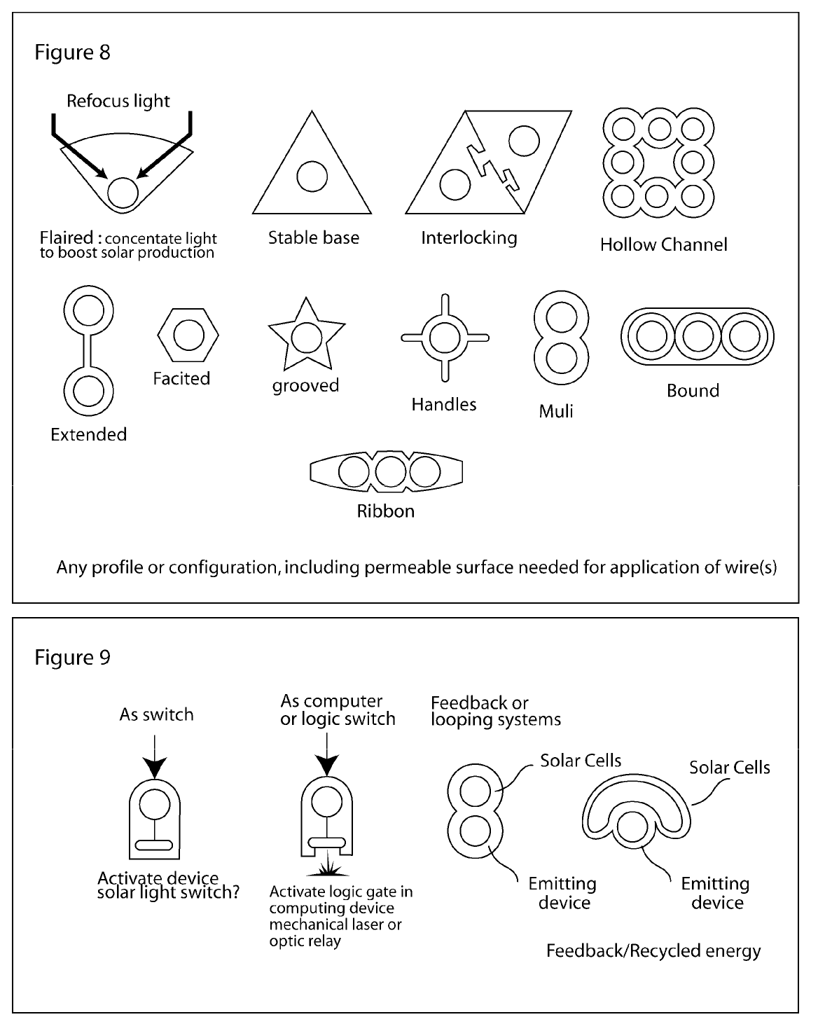

The disclosed wire may be configured in many designs, including the designs shown on FIG. 8. The disclosed designs of configuration shown on FIG. 8 add utility to the disclosed wire. In one configuration shown on FIG. 8, the wire is configured to refocus light to achieve greater solar collection. This configuration is labeled “Flared: concentrate light to boost solar production”. In addition to the configurations shown on FIG. 8, the wire may be bundled and/or twisted so as to create a cable of a larger diameter suitable for use and/or integration with non nano scaled components.

Clear Substrate Material for Support and Optical Advantage for Solar Use

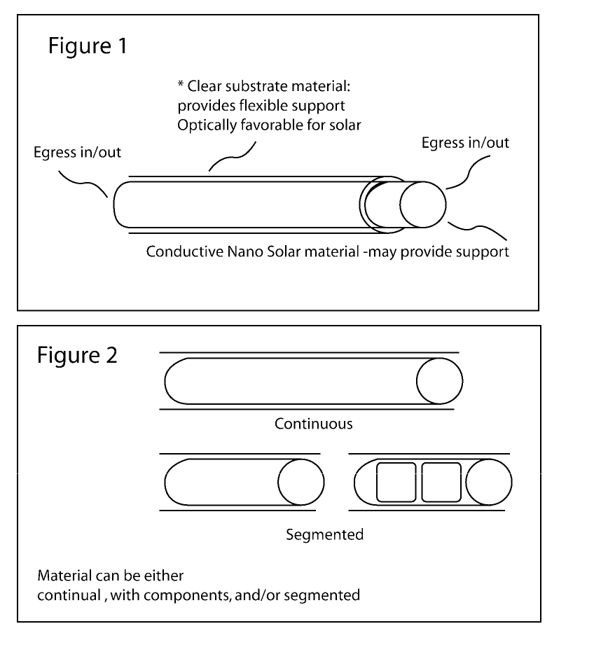

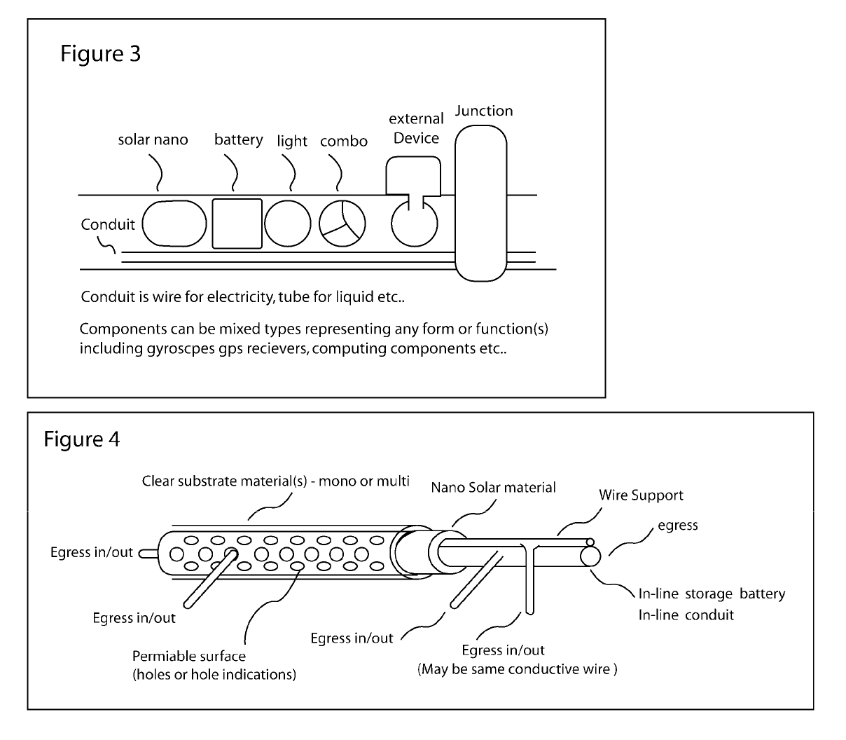

FIG. 1 shows a clear covering material encasing the wire or encasing a hollow tube capable of containing nano components such as the components disclosed on FIG. 3 and FIG. 15. The clear covering or clear substrate material of FIG. 1 allows light and/or solar energy to reach the internal wire or internal hollow tube. The clear substrate material may provide rigid or flexible support to the internal components.

While the substrate material may be clear, the substrate material may be comprised of any material that allows absorption of energy or useful bandwidths of solar radiation. The substrate material may be opaque or tinted and may have means to control heat and/or undesired wave lengths of energy. The substrate material may include nano scale openings or holes that will allow entry of energy or useful bandwidths of solar radiation but yet deny entry to relatively larger elements such as moisture or water drops.

Continual, Component or Segmented Use

FIG. 2 shows the present invention in continuous, component, and segmented form. The multiple forms of the disclosed invention allow the invention to be used as a stand alone product or as a network of products.

For example, with use with some or all of the internal components of FIG. 15, (GPS, gyroscopes, transmitters, receivers, batteries, fuel cells, computer processors, volatile and static memory, hard drives, and other computing components) the disclosed invention may be used as a continual wire to create a personal computer, or may be used in segmented or component form to create a network of computers. The disclosed wire may be twisted or bundled.

FIG. 8 shows segments of wire used to form alternative embodiments of the disclosed invention. Such alternative embodiments include, but are not limited to the shapes of flared, ribbon, extended, facetted, grooved, handles, multi or figure eight, bound, hollow channel, interlocking, and stable base.

FIG. 13 shows segments of wire used create a display or weave pattern. However, such a display may be created by a continuous portion of the wire.

Components In, Attached To, or On the Wire

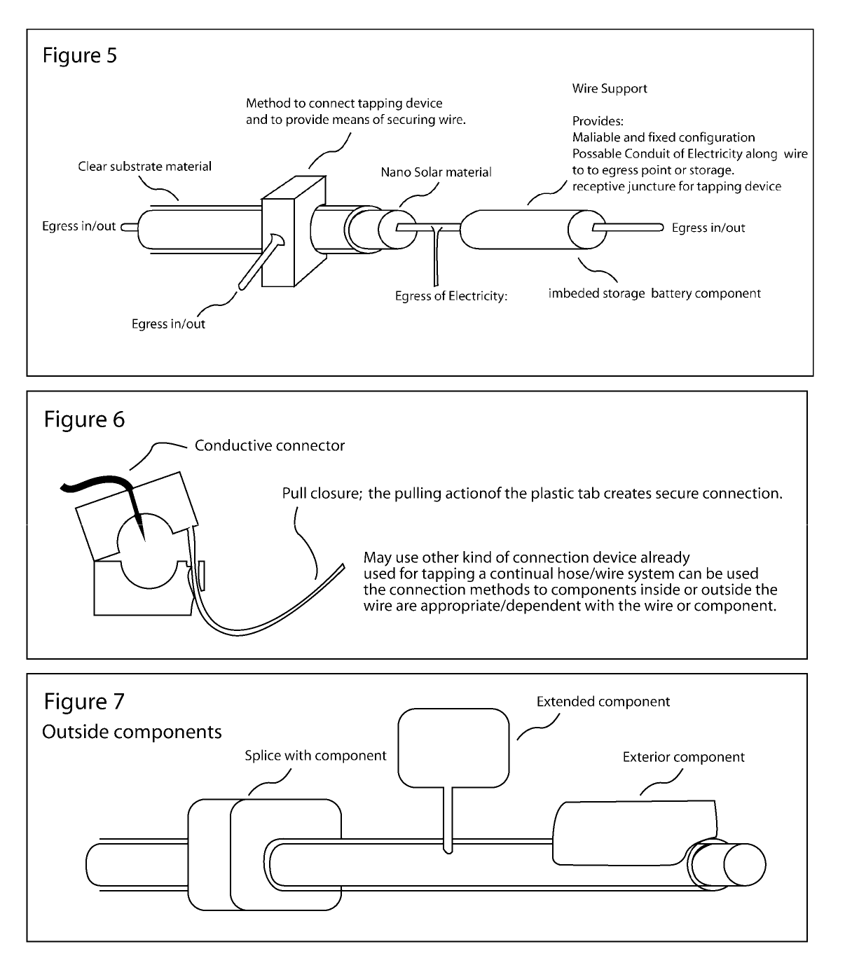

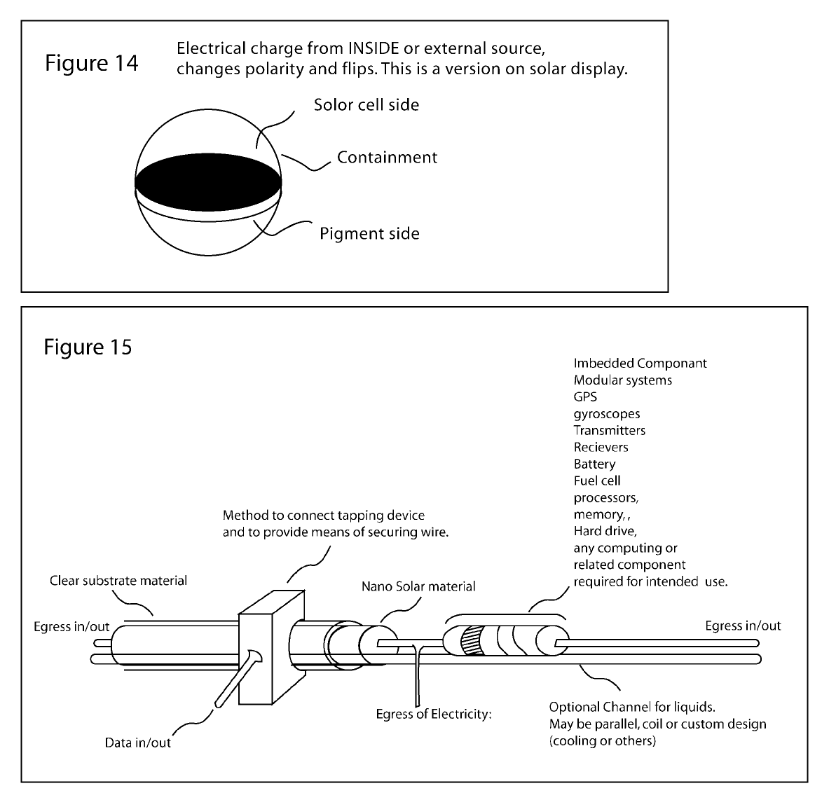

FIG. 3, FIG. 5, FIG. 7, FIG. 14, and FIG. 15 show several of the possible components that may be contained in, on, or attached to the wire. Such components include, but are not limited to, solar collectors, batteries, lights, junctions, solar charge spheres, channels for liquids, other channels, GPS units, gyroscopes, transmitters, radio receivers and computer components. Switches may be located internally and/or externally. Components may be included to allow the wireless transmission of data. Components may be added to receive energy from external sources in high and low light applications.

More particularly, FIG. 5 shows an alternative embodiment wherein the wire contains a conduit for electricity that is encased by optional components such as a battery and solar material. FIG. 15 shows an optional channel for liquids and an electrical conduit encased by a variety of components.

FIG. 14 shows a spherical component usable for a solar or visual display. The sphere contains a solar cell surface and pigmented surface, each attached to opposite sides of an internal two-sided “flipping” circle piece. The flipping circle piece is contained in the center of the sphere. The internal circle piece flips to present the pigmented side or the solar cell side. The sphere has means to flip the interior circle piece when the internal or external electrical polarity is changed. The sphere may be used as a display and may also be a component placed inside the disclosed wire.

Junctions, Splices, and Attachment to Extended or Exterior Components

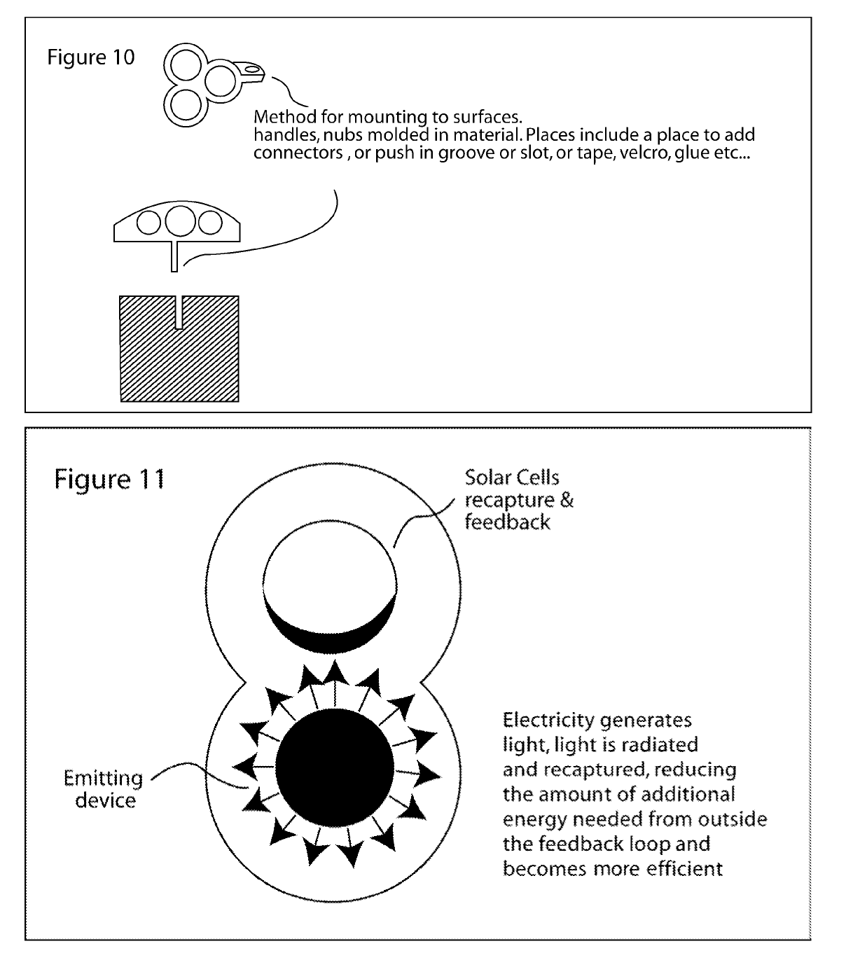

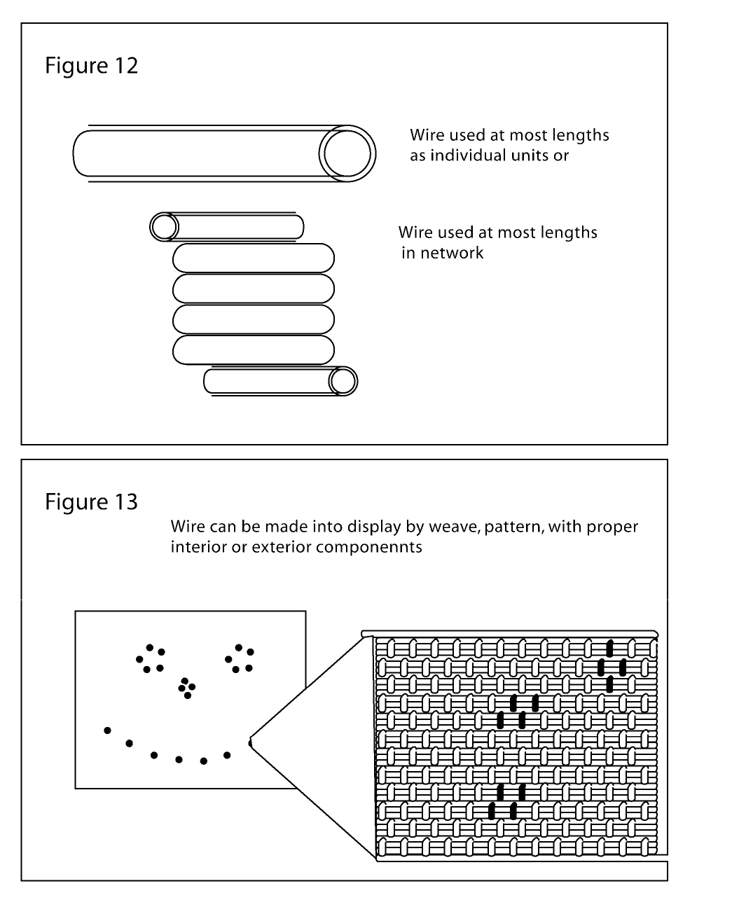

FIG. 6, FIG. 7, and FIG. 10 show means and methods of connecting or tapping into the disclosed wire. Such means and methods may be used to connect the disclosed wire and/or the interior components of the disclosed wire to other objects located on the wire or away from the wire. FIG. 6 shows a pull closure system that embeds a conductive connector into the wire. The pull closure system is shown on FIG. 7 as a “Splice with component”. FIG. 7 shows connections with exterior components as “Extended component”, and components attached to the exterior of the wire as “Exterior component.” The components attached on the wire or attached to the wire but located elsewhere may be of nano scale or larger than nano scale.

FIG. 10 shows means and methods of mounting connections or objects to the surface of the wire. A handle may be used to push connectors or objects into a groove in the wire. The groove or channel may be replaced by other means of connection, such as tape, Velcro, and glue.

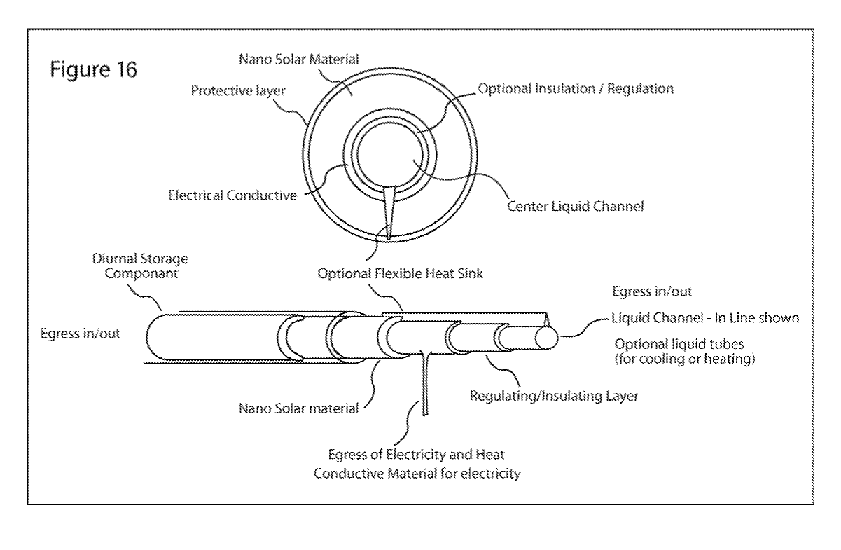

FIG. 16 shows optional channels for liquid cooling or liquid heating. The temperature of the liquid may be between 4 Kelvin (LTSC—low temperature superconduction—Level I) and 150+ Kelvin (for HTSC—high temperature superconduction—Level II) so as to enable superconducting of electricity. Temperatures above 150 Kelvin may be used for used for electrical and non electrical purposes as well as temperatures below 150 Kelvin.

Referring to FIG. 15 and FIG. 16, the channels are variable in size, diameter, and configuration. The channels may be placed in parallel, wrapped or twisted, embedded in line, and/or centrally placed in a cylindrical channel. The walls of the channel may be circular, oval, faceted or in any combination thereof. The channels may contain branches or forks to move, hold or divert liquid. The channels may include layers of insulation to optimize efficiencies or performance in capturing, converting, holding and transporting energy and the resulting magnetic field of energy.

Multiple configured wires may constitute “Multilayering” enabling superconductive behavior as a homogenous system on the quantum level. Multiple configured wires may manage electromagnetism to enhance superconductivity, and to capture and convert electricity. Multilayering may also enable the reduction of electromagnetic vortex interference while simultaneously capturing a portion as electricity by way of component design.

FIG. 16 shows an optional flexible heat sink capable of removing excess head caused by magnetic fields. The disclosed flexible heat sink uses liquid to move heat from warmer to cooler surfaces, such surfaces may be attached to the channel and protrude outward and compose a heat removal component. The disclosed configuration may take advantage of the “Supercomputing Proximity” effect enabling limited super conducting of normally non-super conducting materials. Such a configuration leverages the utility of the cooling system.

The disclosed wire may be configured as mono wire, or any number of combined wires, bundled and combined as required by use and output characteristics. The liquid channel may be coated inside or outside to allow superconductivity in the wire.

Several Uses of the Disclosed Invention

In addition to the uses described above, the disclosed invention has many other uses and inherent methods, including but not limited to the following.

Method to collect and store power and node placement of batteries.

The wire may be elevated above cloud cover to provide solar and/or electrical energy.

The wire may be dragged through the atmosphere to provide energy and radio communication. The wire may convert heat to ultraviolet wave lengths or wave lengths that are within the usable wave length spectrum of the wire.

The wire may be used as rope to secure or mount devices while at the same time providing power and utility via the internal components of the wire.

By extruding the wire with a groove, the wire may be attached to street signs.

The wire may be used as a sensor array to detect and collect light and solar energy.

The wire may be used as a sensor to replace light sensor switches.

The wire may be used as a switch to create or send data in computing systems.

As shown in FIG. 9 the wire may be used as a computer or logic gate.

As shown in FIG. 11, the wire may be configured to act as light/power recapture and feedback device.

As shown on FIG. 9, the wire may be configured to act as an emitting device in a feedback or looping system that recycles energy.

The wire may be used as decorative, architectural, material fill, or art sculpture.

The solar material may take the form of a sphere or other shapes or attach in chain like or hooking fashion. The solar material may attach by means of a translation material such as gas, solid, liquid, or vacuum. The spheres of solar material may have multiple sided surfaces such as the dual interior surface shown in FIG. 14.

The wire may be used as paint and/or placed in asphalt. The wire may provide power, illumination or text messages on the road. On a flight deck of a ship, the wire may be used as paint to guide pilots and to provide power to the ship.

The wire may be coiled around a military ship to act as a sensor to detect laser light, which is often emitted by missiles and other projectiles. The large area of wire covering the ship may provide triangulation information to quickly locate the incoming projectile.

The wire may be placed as outer fabric on a solider, giving the solider a sensor for laser light and/or other energy transmitted by incoming projectiles.

Trucks, cars, airplanes, dirigibles, balloons or other outdoor objects may be covered with the wire or wire in paint form, so as to provide instant and portable solar/electrical generation.

In an airplane, the wire may be released on an emergency basis to acquire electricity.

In a submarine, the wire may be released with a low profile buoy so as to collect power and information from the surface of the water. The wire may be used to tether a balloon floating in the air and attached to the buoy or submarine. The airborne wire may collect additional power and/or provide antenna capability.

While the above is a complete description of the preferred embodiment of the present invention, it is possible to use various alternatives, modifications and equivalents.

What is claimed is:

1. A nano sized transparent tube with round walls made of flexible material with means to contain nano sized solar collectors, batteries, and lights.

2. The tube of claim 1 with conduit capable of accepting metallic wire.

3. The tube of claim 1 with conduit capable of accepting liquid to heat or cool the tube.

4. The tube of claim 1 with additional means to attach input and output wires.

5. The tube of claim 4 with a diameter larger than nano size and with means to attach and be connected to nano and non-nano sized components.

6. The tube of claim 5 with permeable walls.

7. The tube of claim 1 aggregated together to form a component capable of being handled by human hands.

8. The tube of claim 1 with an outer wall surface formed in a prism shape to refocus light entering the tube.

9. The tube of claim 1 attached longitudinally with another tube of claim 1 by means to allow the recapture of energy transmitted by one of the tubes.

10. The tube of claim 1 combined with similar tubes to form a controllable light display.

11. The tube of claim 1 with a slotted wall surface capable of accepting connector pieces.

12. The tube of claim 1 with a pull closure connection device capable of inserting a conductive connector into the tube.

13. A pull closure connection device comprising a conductive connector encased into an upper rectangular piece, a lower rectangular piece pivotally connected to the upper rectangular piece, a pull closure tab connected to the upper rectangular piece and lower rectangular piece by means to pull together the upper and lower rectangular pieces and to cause the conductive connector to penetrate the tube of claim 1.

14. A portable computing apparatus using the tubes of claim 1 to form a network of computer components.

15. The apparatus of claim 14 with means to accept conduit capable of holding liquid.

16. The apparatus of claim 14 with wireless means allowing communication between the tubes containing computer components.

17. The apparatus of claim 14 with means to illuminate the tubes and form visible messages.

18. The apparatus of claim 14 with computer components comprising CPUs, batteries, and memory.

19. The apparatus of claim 18 with computer components further comprising means of energy collection and energy transmission.

20. The apparatus of claim 19 with tubes that are round, flexible and capable of accepting solar energy at 360 degrees around the tubes and wherein the tubes are capable of wrapping around other objects.
